(19) United States
(12) Patent Application Publication
(10) Pub. No.: US 2008/0217666 A1
(43) Pub. Date: Sep. 11, 2008

(54) CMOS IMAGE SENSOR AND METHOD OF FABRICATING THE SAME

(75) Inventor: Ching-Hung Kao, Hsinchu Hsien (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/683,059

(22) Filed: Mar. 7, 2007

(51) Int. Cl. H01L 31/113; H01L 31/18

(52) U.S. Cl. 257/290; 438/57; 257/E31.085; 257/E21.611

(57) ABSTRACT

A floating node structure of a CMOS image sensor disposed in a floating node region defined by an isolation structure of a substrate is described. The floating node structure comprises an n-doped region within the floating node region, a p-well surrounding the periphery and the bottom of the n-doped region in the substrate within the folating node region, a surface passivation layer disposed at least on the surface of the p-well, and a contact plug coupling the n-doped region to a source follower transistor of the CMOS image sensor.

### BACKGROUND OF THE INVENTION

1. Field of the Invention

The present invention relates to an image sensor, and more particularly, the present invention relates to a floating node structure of a complementary metal oxide semiconductor (CMOS) image sensor.

2. Description of Related Art

The process of fabricating a complementary metal-oxide-semiconductor image sensor (CMOS image sensor, CIS) is compatible with the process of fabricating a complementary metal-oxide-semiconductor (CMOS) transistor. Therefore, CMOS image sensors and CMOS transistors can be easily integrated with other peripheral circuits on a single chip to significantly lower the power consumption and the manufacturing costs of image sensors. In recent years, CMOS image sensors have replaced charge-coupled devices (CCD) in the low-end applications and are becoming more and more predominant.

A CMOS image sensor comprises a photodiode and a plurality of transistors, wherein the photodiode is constructed from a P-N junction formed by combining an N-doped region and a P-substrate. The transistors are N-type transistors having an N-type gate (N-poly NMOS). Currently, CMOS image sensors are designed based on architectures such as 3-transistor (3T) configuration and 4-transistor (4T) configuration.

A typical 3T configuration refers to a CMOS image sensor comprising of a reset transistor (Rx), a source follower transistor (Dx), a select transistor (Sx) and a photodiode. However, such configuration causes high dark current, increases readout noise and affects the image quality, thus reducing the performance of the device. Hence, 4T configuration is implemented more frequently. FIG. 1 schematically illustrates a conventional 4T CMOS image sensor.

In FIG. 1, the CMOS image sensor comprises a substrate 100, a transfer transistor 102 disposed on the substrate 100, a reset transistor 104, a source follower transistor 106, a select transistor 108, a photodiode 110 disposed in the substrate 100, a floating node 112 disposed in the substrate 100, and a P-well 114 disposed in the substrate 100. Since the 4T CMOS image sensor comprises the transfer transistor 102, the problem with the 3T CMOS image sensor having very high dark current can be improved.

In the 4T CMOS image sensor, the floating node 112 is coupled to the source follower transistor 106 via a contact plug in order to transmit the signal received from the photodiode 110. Nevertheless, the floating node 112 is a heavily N-doped region, leakage thus occurs at the P-N junction between the floating node 112 and the P-well 114, resulting in image distortion. Due to this kind of leakage, certain application such as global shutter cannot be achieved. Moreover, the leakage gets worse as the temperature increases.

### SUMMARY OF THE INVENTION

The present invention is to provide a CMOS image sensor that can eliminate the occurrence of leakage at the floating node.

The present invention is to provide a CMOS image sensor that can reduce image distortion.

The present invention provides a floating node structure of a CMOS image sensor. The floating node structure is disposed on a floating node region of an active region defined by an isolation structure in a substrate, which comprises a first conductive type doped region, a second conductive type well, a surface passivation layer and a contact plug. The first conductive type doped region is disposed within the floating node region. The second conductive type well is disposed within the floating node region, surrounding the periphery and the bottom of the first conductive type doped region. The surface passivation layer is disposed at least on the surface of the second conductive type well. The contact plug is coupled to the first conductive type doped region.

According to the embodiment of the present invention, in the floating node structure of the CMOS image sensor, the surface passivation layer may be either first conductive type or second conductive type.

According to the embodiment of the present invention, in the floating node structure of the CMOS image sensor, the doping concentration of the surface passivation layer is approximately 1×10¹²-1×10¹³/cm³.

According to the embodiment of the present invention, in the floating node structure of the CMOS image sensor, the first conductive type doped region is a first conductive type lightly doped region. In addition, the floating node structure further comprises a first conductive type heavily doped region disposed in the first conductive type lightly doped region.

According to the embodiment of the present invention, in the floating node structure of the CMOS image sensor, the doping concentration of the first conductive type heavily doped region is approximately 1×10¹⁴-1×10¹⁵/cm³.

According to the embodiment of the present invention, in the floating node structure of the CMOS image sensor, the doping concentration of the first conductive type lightly doped region is approximately 1×10¹²-1×10¹³/cm³.

According to the embodiment of the present invention, the floating node structure of the CMOS image sensor further comprises a metal silicide layer first disposed between the contact plug and the first conductive type heavily doped region.

According to the embodiment of the present invention, in the floating node structure of the CMOS image sensor, the surface passivation layer is first conductive type and extends to cover the first conductive type lightly doped region, neighboring upon the metal silicide layer disposed on the first conductive type heavily doped region.

According to the embodiment of the present invention, the floating node structure of the CMOS image sensor further comprises a second conductive type field region disposed peripherally around the second conductive type well and the isolation structure, extending to the bottom of the isolation structure.

According to the embodiment of the present invention, in the floating node structure of the CMOS image sensor, the surface passivation layer is second conductive type and extends to cover the second conductive type field region, neighboring upon the isolation structure.

According to the embodiment of the present invention, in the floating node structure of the CMOS image sensor, the doping concentration of the second conductive type field region is approximately 1×10¹²-1×10¹³/cm³.

The present invention also provides a method for fabricating the floating node of the CMOS image sensor. This method begins with forming an isolation structure in a substrate to define an active region, wherein the active region comprises a floating node region. Next, a second conductive type well is formed in the floating node region of the substrate. A first conductive type doped region is formed in the second conductive type well. A surface passivation layer is formed on the second conductive type well. Thereafter, a contact plug is formed on the substrate, electrically coupling to the first conductive type doped region.

According to the embodiment of the present invention, in the method for fabricating the floating node of the CMOS image sensor, the surface passivation layer is either first conductive type or second conductive type.

According to the embodiment of the present invention, in the method for fabricating the floating node of the CMOS image sensor, the doping concentration of the surface passivation layer is approximately 1×10¹²-1×10¹³/cm³.

According to the embodiment of the present invention, in the method for fabricating the floating node of the CMOS image sensor, the method for fabricating the surface passivation layer comprises an ion implantation process, wherein the ion implantation energy is below 40 KeV.

According to the embodiment of the present invention, in the method for fabricating the floating node of the CMOS image sensor, the first conductive type doped region is a first conductive type lightly doped region. In addition, the fabrication method further comprises forming a first conductive type heavily doped region in the first conductive type lightly doped region after the formation of the surface passivation layer.

According to the embodiment of the present invention, in the method for fabricating the floating node of the CMOS image sensor, the doping concentration of the first conductive type heavily doped region is approximately 1×10¹⁴-1×10¹⁵/cm³.

According to the embodiment of the present invention, in the method for fabricating the floating node of the CMOS image sensor, the method for fabricating the first conductive type heavily doped region comprises an ion implantation process, wherein the ion implantation energy is 40-60 KeV.

According to the embodiment of the present invention, in the method for fabricating the floating node of the CMOS image sensor, the doping concentration of the first conductive type lightly doped region is approximately 1×10¹²-1×10³/cm³.

According to the embodiment of the present invention, in the method for fabricating the floating node of the CMOS image sensor, the method for fabricating the first conductive type lightly doped region comprises an ion implantation process, wherein the ion implantation energy is below 100 KeV.

According to the embodiment of the present invention, in the method for fabricating the floating node of the CMOS image sensor, the first conductive type lightly doped region is formed simultaneously with a source/drain extension region of a first conductive type channel transistor of the CMOS image sensor.

According to the embodiment of the present invention, in the method for fabricating the floating node of the CMOS image sensor, the first conductive type heavily doped region is formed simultaneously with a source/drain contact region of a first conductive type channel transistor of the CMOS image sensor.

According to the embodiment of the present invention, in the method for fabricating the floating node of the CMOS image sensor, the first conductive type lightly doped region is formed after the formation of the first conductive type heavily doped region.

According to the embodiment of the present invention, the method for fabricating the floating node of the CMOS image sensor further comprises forming a metal silicide layer on the first conductive type heavily doped region.

According to the embodiment of the present invention, in the method for fabricating the floating node of the CMOS image sensor, the surface passivation layer is first conductive type and extends to cover the first conductive type lightly doped region, neighboring upon the metal silicide layer disposed on the first conductive type heavily doped region.

According to the embodiment of the present invention, the method for fabricating the floating node of the CMOS image sensor further comprises forming a second conductive type field region peripherally around the second conductive type well and the isolation structure, extending to the bottom of the isolation structure.

According to the embodiment of the present invention, in the method for fabricating the floating node of the CMOS image sensor, the surface passivation layer is second conductive type and extends to cover the second conductive type field region, neighboring upon the isolation structure.

The floating node of the CMOS image sensor of the present invention can eliminate the occurrence of leakage at the floating node.

The floating node of the CMOS image sensor of the present invention can reduce image distortion.

In order to the make the aforementioned and other objects, features and advantages of the present invention comprehensible, a preferred embodiment accompanied with figures are described in detail below.

### BRIEF DESCRIPTION OF THE DRAWINGS

FIG. 1 schematically illustrates a conventional 4T CMOS image sensor.

FIG. 2 is a schematic top view illustrating a CMOS image sensor according to an embodiment of the present invention.

FIG. 3 is a schematic cross-sectional view illustrating the structure along III-III line of FIG.2.

FIG. 4 is a schematic cross-sectional view illustrating a floating node structure according to another embodiment of the present invention.

FIG. 5 is a schematic cross-sectional view illustrating a floating node structure according to another embodiment of the present invention.

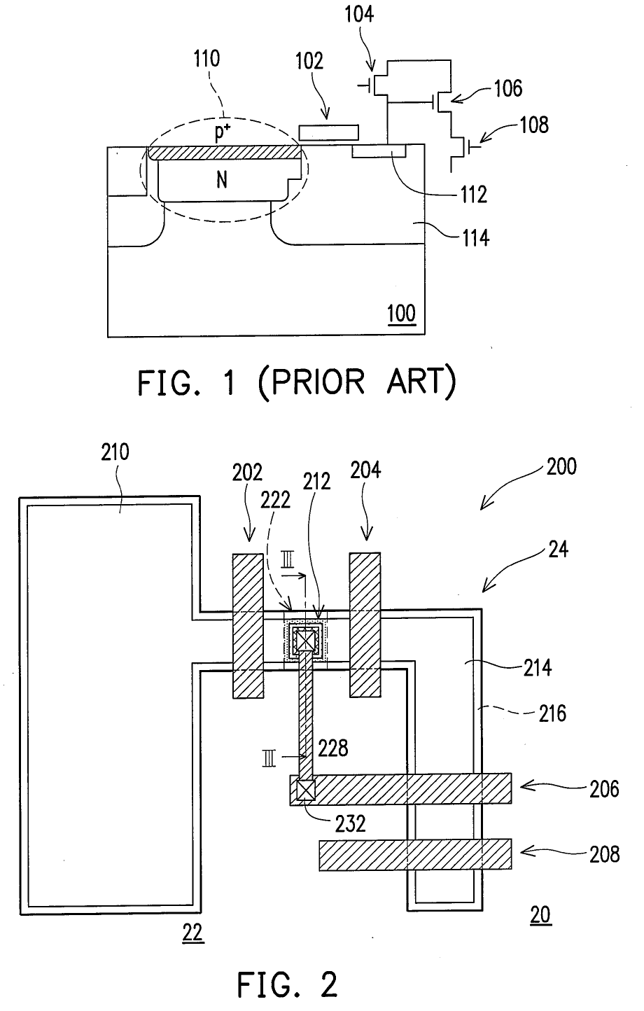

### DESCRIPTION OF EMBODIMENTS

FIG. 2 schematically illustrates a top view of a CMOS image sensor according to an embodiment of the present invention.

In FIG. 2, a CMOS image sensor 200 is fabricated on an active region 24 defined by an isolation structure 22 of a substrate 20. The CMOS image sensor comprises a transfer transistor 202, a reset transistor 204, a source follower transistor 206, a select transistor 208, a photodiode 210, and a floating node structure 212.

The substrate 20 may be a P-type Si-substrate. The isolation structure 22 may be a shallow trench isolation (STI) structure. The floating node structure 212 is disposed on a floating node region 222 located between the transfer transistor 202 and the reset transistor 204 and defined by the isolation structure 22. The floating node structure 212 may be electrically connected to the source follower transistor 206 via a contact plug 224.

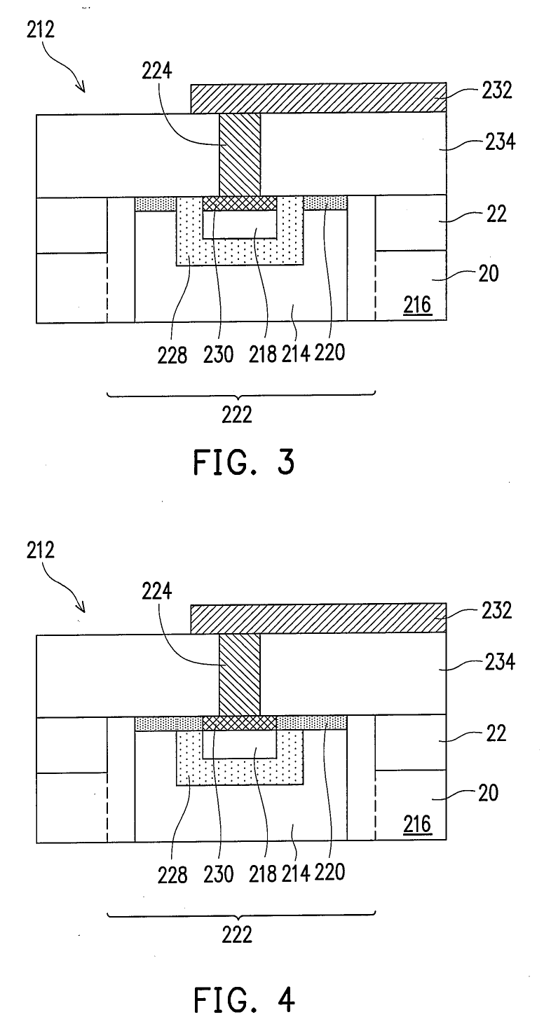

FIG. 3 is a schematic cross-sectional view illustrating the floating node structure 212 along line III-III of FIG. 2.

In FIG. 3, the floating node structure 212 is disposed on a floating node region 222 defined by the isolation structure, which comprises an N-doped region 228, a P-well 214, a surface passivation layer 220 and a contact plug 224.

The N-doped region 228 is disposed in the floating node region 222. The N-doped region 228 may be implanted with n-type dopant such as phosphorous or arsenic. The N-doped region 228 may be fabricated by ion implantation. The ion implantation process may be achieved at a tilted angle and the ion implantation energy may be below 100 KeV.

In one embodiment, the N-doped region 228 is a lightly N-doped region, wherein the doping concentration may be approximately 1×10¹²-1×10¹³/cm³ and the lightly doped region comprises a heavily N-doped region 218. Since the N-doped region 228 is a lightly doped region, the junction between the lightly N-doped region 228 and the P-well 214 forms a weaker electric field, reducing the occurrence of leakage. The doping concentration is higher and the resistance is lower for the heavily N-doped region 218, so that the contact resistance between the heavily doped region and the contact plug 224 is reduced. The heavily N-doped region 218 may be implanted with n-type dopant such as phosphorous or arsenic and the doping concentration may be approximately 1×10¹⁴-1×10¹⁵/cm³. The heavily N-doped region 218 may be fabricated by ion implantation. The ion implantation energy may be within the range of 40 KeV to 60 KeV.

In another embodiment, the N-doped region 228 is a lightly doped region, wherein the lightly doped region comprises a heavily doped region 218 and a metal silicide layer 230 disposed on the heavily N-doped region 218. The metal silicide layer 218 can further reduce the resistance and allow faster transmission of electrical charges. The metal silicide layer 230 comprises a metal silicide with a refractory metal selected from the group consisting of nickel, cobalt, titanium, copper, molybdenum, tantalum, tungsten, erbium, zirconium, platinum and an alloy comprising one or more of these metals.

The P-well 214 is disposed in the floating node region 222, surrounding the periphery and the bottom of the N-doped region 228. The P-well 214 may be implanted with p-type dopants such as boron or boron difluoride and the fabrication thereof may be ion implantation.

To prevent leakage from the surface of the substrate 20 and around the isolation structure 22, a P-type field region 216 may be selectively fabricated. The P-type field region 216 is disposed around the periphery of the P-well 214 in a floating region 322 and around the isolation structure 22, extending to the bottom of the isolation structure 22. The P-type field region 216 may be implanted with p-type dopants such as boron or boron difluoride and the fabrication thereof may be ion implantation.

The contact plug 224 disposed in a dielectric layer 234 is coupled to the heavily N-doped region 218 and electrically connected to the source follower transistor 206 via a conductive line 232. The materials for fabricating the contact plug 224 comprise conductor materials such as metals, including tungsten, or doped polysilicon.

The surface passivation layer covers at least the surface of the P-well 214. The substrate 20 may be fabricated using silicon and the materials for fabricating the isolation structure or the dielectric layer is usually silicon dioxide. Since the materials for fabricating the substrate and the isolation structure/the dielectric layer are different, the atomic structure of the substrate and the isolation structure/the dielectric layer are different as well. Therefore, leakage will occur at the junction between the substrate and the isolation structure/the dielectric layer because of the difference in the atomic structure. Forming the surface passivation layer 220 on the surface of the P-well 214 can eliminate the occurrence of leakage. The surface passivation layer 220 may be an N-doped region or a P-doped region, wherein the doping concentration is approximately 1×10¹²-1×10¹³/cm³. When the surface passivation layer 220 is a P-doped region, it may be implanted with p-type dopants such as boron or boron difluoride. When the surface passivation layer is an N-doped region, it may be implanted with n-type dopants such as phosphorous or arsenic. The method for fabricating the surface passivation layer 220 may be ion implantation, wherein the ion implantation energy may be below 40 KeV.

In the floating node structure 212, most of the elements are implanted into the substrate 20, therefore, the materials for those elements are almost identical with that of the substrate 20. However, the materials for fabricating the metal silicide layer 230 for lowering the resistance and that for the isolation structure 22 defining the floating node region 222 are very different from the materials fabricating the substrate 20. As a result, leakage occurs easily at the junction. Hence, the above-mentioned surface passivation layer 220, besides being disposed on the surface of the P-well 214, may also be extended to junctions formed by elements fabricated with materials different from that of the substrate when required. For instance, the surface passivation layer 220 may be extended from the P-well 214 to the top of the neighboring P-type field region 216 to be in contact with the isolation structure 22 or it may be extended to the top of the lightly N-doped region 228 to be in contact with the metal silicide layer 230.

In FIG. 4, according to an embodiment, the surface passivation layer 220 is an N-doped region disposed on the surface of the P-well 214 and extends to the top of the lightly N-doped region 228 and connects to the metal silicide layer 230 on the heavily N-doped region 218 to further eliminate the occurrence of leakage at the junction formed between the metal silicide layer 230 and the lightly N-doped region 228.

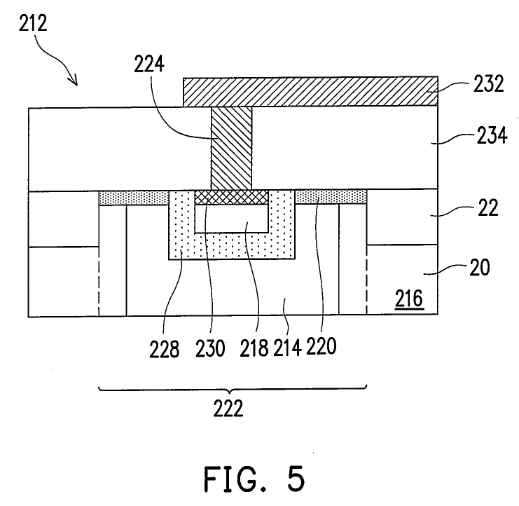

In FIG. 5, according to another embodiment, the surface passivation layer 220 is a P-doped region disposed on the surface of the P-well 214 and extends to the top of the P-type field region 216 and connects to the corner of the isolation structure 22 to further eliminate the occurrence of leakage at the upper corner of the isolation structure 22.

In FIG. 2 and FIG. 3, a fabrication method for the floating node structure 212 of the CMOS image sensor 200 of the present invention begins with forming the active region 24 defined by the isolation structure 22 in the substrate 20. In the active region 24, the region between a region predetermined for forming the transfer transistor 202 and the reset transistor 204 is the floating node region 222. The fabrication method for the isolation structure 22 begins with forming a shallow trench in the substrate 20, and then, fill the shallow trench with insulation materials such as silicon dioxide.

Next, a P-well 214 is formed in the substrate 20. The P-well 214 may be fabricated by ion implantation and it may be implanted with p-type dopants such as boron or boron difluoride.

Next, a p-typed field region 216 is formed around the periphery of the P-well 214 in the floating node region 222 of the substrate 20 and around the isolation structure 22. The P-well 216 may be fabricated by ion implantation and it may be implanted with p-type dopant such as boron or boron difluoride.

After forming the gate dielectric layers and the gates of the transfer resistor 202 of the CMOS image sensor 200, the reset transistor 204, the source follower transistor 206 and the select transistor 208 and during the formation of the source/drain extension region of the transistor, a lightly N-doped region 228 may be formed in the P-well 214 of the floating node region 222 simultaneously. The ion implantation energy may be below 100 KeV and it may be implanted with n-type dopants such as phosphorous or arsenic. The doping concentration may be approximately 1×10¹²-1×10¹³/cm³.

Thereafter, a surface passivation layer is formed on the P-well 214. The surface passivation layer 220 may be an N-doped region or a P-doped region, wherein the doping concentration is approximately 1×10¹²-1×10¹³/cm³. When the surface passivation layer 220 is an N-doped region, the surface passivation layer 220 forms on the P-well 214 and extends to the surface of the lightly N-doped region 228 as shown in FIG. 4. The p-type dopant used may be boron or boron difluoride. When the surface passivation layer 220 is an N-doped region, the surface passivation layer 220 forms on the P-well 214 and extends to the surface of the p-typed field region 216 as shown in FIG. 5. The p-type dopant used may be phosphorous or arsenic. The method for fabricating the surface passivation layer 220 may be ion implantation, wherein the ion implantation energy may be below 100 KeV.

After forming the spacers of the transfer transistor 202, the reset transistor 204, the source follower transistor 206 and the select transistor 208, either during or after the formation of the source/drain contact region, a heavily N-doped region 218 may be formed in the lightly N-doped region 228 of the floating node region 222. The heavily N-doped region 218 may be fabricated by ion implantation. The ion implantation energy may be within the range of 40 KeV to 60 KeV. The heavily N-doped region 218 may be implanted with n-type dopants such as phosphorous or arsenic. The doping concentration may be approximately 1×10¹⁴-1×10¹⁵/cm³.

The above-mentioned lightly N-doped region 228 is formed simultaneously with the formation of the source/drain extension regions of the transfer resistor 202, the reset transistor 204, the source follower transistor 206, and the select transistor 208 of the CMOS image sensor 200. Nonetheless, in another embodiment, the lightly N-doped region 228 may be formed after the formation of the spacers of the transfer resistor 202, the reset transistor 204, the source follower transistor 206, the select transistor 208, and the heavily N-doped region 218. In this embodiment, the lightly N-doped region 228 may be fabricated by ion implantation process at a tilted angle, allowing deep penetration and covering the heavily N-doped region 218 without punch-through.

Thereafter, the metal silicide layer 230 is formed on the heavily N-doped region 218. The metal silicide layer 230 may be fabricated by self-aligned silicide (salicid) process. For instance, a metal layer is first formed on the substrate 20. The metal used for fabricating the metal layer may be a refractory metal selected from the group consisting of nickel, cobalt, titanium, copper, molybdenum, tantalum, tungsten, erbium, zirconium, platinum and an alloy comprising one or more of these metals. Afterwards, an annealing process is performed to cause the silicon in the substrate 20 to react with the metal layer to form a metal silicide having a lower resistance. Thereafter, the unreacted metal layer is removed.

Next, the dielectric layer 234 is formed on the substrate 20 and the contact plug 224 is formed in the dielectric layer 234, electrically coupling to the N-doped region 228. The dielectric layer 234 may be fabricated by materials such as silicon oxide and the fabrication method thereof may be a chemical vapor deposition process. The contact plug 224 may be fabricated by forming a contact opening in the dielectric layer 234, and then fill the contact opening with conductor materials such as metals, including tungsten or doped polysilicon.

In the above embodiment, the floating node structure is illustrated by a P-type substrate, an N-doped region and a P-well. However, the present invention is not limited thereto. Anybody skilled in the art can make some modifications and alteration such as using N-type substrate, P-doped region and N-well instead without departing from the spirit and the scope of the present invention.

Accordingly, the floating node structure of the CMOS image sensor of the present invention comprises a surface passivation layere that may be disposed on the surface of a first conductive type well or extend to be in contact with the isolation structure, or further extend to be in contact with the metal silicide layer, eliminating the occurrence of leakage caused by difference in the materials for fabricating junctions and preventing image distortion.

Furthermore, in the floating node structure of the CMOS image sensor of the present invention, a second conductive type lightly doped region is comprised between the second conductive type heavily doped region and the first conductive type well, wherein the junction between the second conductive type lightly doped region and the first conductive type well results in smaller electric field, eliminating the occurrence of leakage at junction and preventing image distortion.

What is claimed is:

1. A floating node structure of the complementary metal-oxide-semiconductor image sensor, which is disposed on a floating node region defined by an isolation structure of a substrate, comprising:
a first conductive type doped region disposed within the floating node region;
a second conductive type well disposed within the floating node region, surrounding the periphery and the bottom of the first conductive type doped region;
a surface passivation layer disposed at least on the surface of the second conductive type well; and
a contact plug coupled to the first conductive type doped region.

2. The floating node structure of the complementary metal-oxide-semiconductor image sensor of claim 1, wherein the surface passivation layer being either first conductive type or second conductive type.

3. The floating node structure of the complementary metal-oxide-semiconductor image sensor of claim 1, wherein the surface passivation layer having a doping concentration of approximately 1×10¹²-1×10¹³/cm³.

4. The floating node structure of the complementary metal-oxide-semiconductor image sensor of claim 1, wherein the first conductive type doped region being a first conductive type lightly doped region and the floating node structure further comprising a first conductive type heavily doped region disposed in the first conductive type lightly doped region.

5. The floating node structure of the complementary metal-oxide-semiconductor image sensor of claim 4, wherein the first conductive type heavily doped region having a doping concentration of approximately 1×10¹⁴-1×10¹⁵/cm³.

6. The floating node structure of the complementary metal-oxide-semiconductor image sensor of claim 4, wherein the first conductive type lightly doped region having a doping concentration of approximately 1×10¹²-1×10¹³/cm³.

7. The floating node structure of the complementary metal-oxide-semiconductor image sensor of claim 4, further comprising a metal silicide layer disposed between the contact plug and the first conductive type heavily doped region.

8. The floating node structure of the complementary metal-oxide-semiconductor image sensor of claim 7, wherein the surface passivation layer is first conductive type, extending to cover the first conductive type lightly doped region and neighboring upon the metal silicide layer disposed on the first conductive type heavily doped region.

9. The floating node structure of the complementary metal-oxide-semiconductor image sensor of claim 1, further comprising a second conductive type field region disposed peripherally around the second conductive type well and around the isolation structure, extending to the bottom of the isolation structure.

10. The floating node structure of the complementary metal-oxide-semiconductor image sensor of claim 9, wherein the surface passivation layer is second conductive type, extending to cover the second conductive type field region and neighboring upon the isolation structure.

11. The floating node structure of the complementary metal-oxide-semiconductor image sensor of claim 9, wherein the second conductive type filed region having a doping concentration of approximately 1×10¹²-1×10¹³/cm³.

12. A method of fabricating a complementary metal-oxide-semiconductor image sensor, comprising:
forming an isolation structure in a substrate to define a floating node region;
forming a second conductive type well in the floating node region of the substrate;
forming a first conductive type doped region in the second conductive type well;
forming a surface passivation layer on the second conductive type well; and
forming a contact plug on the substrate, electrically coupling to the first conductive type doped region.

13. The method of fabricating a complementary metal-oxide-semiconductor image sensor of claim 12, wherein the surface passivation layer being a doped region that is either first conductive type or second conductive type.

14. The method of fabricating a complementary metal-oxide-semiconductor image sensor of claim 13, wherein the surface passivation layer having a doping concentration of approximately 1×10¹²-1×10¹³/cm³.

15. The method of fabricating a complementary metal-oxide-semiconductor image sensor of claim 13, wherein the method for fabricating the surface passivation layer comprising an ion implantation process using an ion implantation energy being below 40 KeV.

16. The method of fabricating a complementary metal-oxide-semiconductor image sensor of claim 11, wherein the first conductive type doped region is a first conductive type lightly doped region and the fabrication method further comprising forming a first conductive type heavily doped region in the first conductive type lightly doped region after the formation of the surface passivation layer.

17. The method of fabricating a complementary metal-oxide-semiconductor image sensor of claim 16, wherein the first conductive type heavily doped region having a doping concentration of approximately 1×10¹⁴-1×10¹⁵/cm³.

18. The method of fabricating a complementary metal-oxide-semiconductor image sensor of claim 16, wherein the method for fabricating the first conductive type heavily doped region comprising an ion implantation process and the ion implantation energy is 40-60 KeV.

19. The method of fabricating a complementary metal-oxide-semiconductor image sensor of claim 16, wherein the first conductive type lightly doped region having a doping concentration of approximately 1×10¹²-1×10¹³/cm³.

20. The method of fabricating a complementary metal-oxide-semiconductor image sensor of claim 16, wherein the method for fabricating the first conductive type lightly doped region comprises an ion implantation process using ion implantation energy being below 100 KeV.

21. The method of fabricating a complementary metal-oxide-semiconductor image sensor of claim 16, wherein forming the first conductive type lightly doped region simultaneously with the formation of a source/drain extension region of a first conductive type channel transistor of the CMOS image sensor.

22. The method of fabricating a complementary metal-oxide-semiconductor image sensor of claim 16, wherein forming the first conductive type heavily doped region simultaneously with the formation of a source/drain contact region of a first conductive type channel transistor of the CMOS image sensor.

23. The method of fabricating a complementary metal-oxide-semiconductor image sensor of claim 22, wherein forming the first conductive type lightly doped region after the first conductive type heavily doped region is formed.

24. The method of fabricating a complementary metal-oxide-semiconductor image sensor of claim 16, further comprises forming a metal silicide layer on the first conductive type heavily doped region.

25. The method of fabricating a complementary metal-oxide-semiconductor image sensor of claim 16, wherein the surface passivation layer is first conductive type extending to cover the first conductive type lightly doped region, neighboring upon the metal silicide layer disposed on the first conductive type heavily doped region.

26. The method of fabricating a complementary metal-oxide-semiconductor image sensor of claim 12, further comprising forming a second conductive type field region disposed peripherally around the second conductive type well and around the isolation structure, extending to the bottom of the isolation structure.

27. The method of fabricating a complementary metal-oxide-semiconductor image sensor of claim 26, wherein the surface passivation layer is second conductive type, extending to cover the second conductive type field region and neighboring upon the isolation structure.
